(19) United States
(12) Patent Application Publication
(10) Pub. No.: US 2019/0134719 A1
(43) Pub. Date: May 9, 2019

(54) DRILL STRUCTURE

(71) Applicant: TCT Global Limited, Tsuen Wan (HK)

(72) Inventors: Sung Hao CHIEN, Lu-Chu (TW); Li Yi CHAO, Lu-Chu (TW); Feng Yu LIN, Lu-Chu (TW); Cheng Chia LEE, Lu-Chu (TW); Ming Yuan ZHAO, Lu-Chu (TW)

(21) Appl. No.: 16/126,767

(22) Filed: Sep. 10, 2018

(30) Foreign Application Priority Data
Nov. 3, 2017 (TW) 106138031

(51) Int. Cl. B23B 51/02; H05K 3/00

(52) U.S. Cl. CPC B23B 51/02; H05K 3/0047; B23B 2251/04; B23B 2251/408; B23B 2251/18; B23B 2251/14; B23B 2251/426

(57) ABSTRACT

A drill structure comprises a shank part and a flute part disposed on one end of the shank part. The front region of the flute part has a web. Two sides of the web are tilted backward to form a first cutting face and a second cutting face. At least one flute is formed on the outer surface of the flute part. The flute part has a bit core in the center thereof. The radius of the cross section of the bit core is defined as the web thickness. The first cutting face includes a first primary cutting face and a first secondary cutting face. The second cutting face includes a second primary cutting face and a second secondary cutting face. The first cutting edge of the first primary cutting face is not parallel with the first connection edge. The width of the primary cutting face width is larger than the web thickness. The drill structure has high cutting ability and long service life.

### BACKGROUND OF THE INVENTION

### 1. Field of the Invention

The present invention relates to a drill structure, particularly to a drill structure having high cutting ability and long service life.

### 2. Description of the Prior Art

With advance of science and technology, the circuits on a printed circuit board (PCB) are growing miniaturized to achieve high density and high precision. Confronting the highly competitive environment demanding high quality, high productivity and fast supply, the manufacturers require the micro drills used in PCB to have higher and higher precision, strength, feed rate, and surface finish. In practical fabrication, the manufacturer is likely to stack a plurality of PCB's and drill them simultaneously so as to increase the fabrication efficiency and decrease the fabrication cost. In such a case, the micro drill needs to have longer length and sufficient chip discharge capability.

A micro drill involves a shank part and a flute part connected with the shank part. The front end of the flute part has a cutting face structure 10, as shown in FIG. 1. The cutting face structure 10 includes two primary cutting faces 12 and 12′ and two secondary cutting faces 14 and 14′, which are symmetrically arranged with respect to a static tip point 16 and used to cut workpieces. In the design shown in FIG. 1, the cutting edges 121 and 121′ are respectively formed on the laterals of the primary cutting faces 12 and 12′. Because of having a shorter cutting length, the cutting edges 121 and 121′ have a smaller cutting force. Further, the drill structure has a shorter service life because the primary cutting faces have a smaller area.

### SUMMARY OF THE INVENTION

One objective of the present invention is to provide a drill structure having high cutting ability and long service life, whereby to solve the abovementioned problems.

In order to achieve the abovementioned objective, one embodiment of the present invention proposes a drill structure, which comprises a shank part and a flute part disposed on one end of the shank part. The front region of the flute part has a cutting face structure. The cutting face structure has a web, and the web has a tip. Two sides of the web are tilted backward to form a first cutting face and a second cutting face. At least one first outer rim of the first cutting face is spirally extended backward around the outer surface of the flute part to form at least one first helical side edge and at least one first helical groove. The flute part has a bit core. The radius of the cross section of the bit core is defined as the web thickness. The first cutting face includes a first primary cutting face and a first secondary cutting face. The second cutting face includes a second primary cutting face and a second secondary cutting face. The apexes of the first primary cutting face, the first secondary cutting face, the second primary cutting face and the second secondary cutting face intersect at the tip. The first primary cutting face has a first cutting edge, a first prismatic edge, a first connection edge and a first outer edge. The first prismatic edge is connected with the second secondary cutting face. The first connection edge is connected with the first secondary cutting face. One end of the first prismatic edge and one end of the first connection edge intersect at the tip. One end of the first cutting edge is connected with one end of the first prismatic edge, which is far away from the tip. The other end of the first cutting edge is extended to a direction far away from the first connection edge to make the first cutting edge not parallel with the first connection edge. Two ends of the first outer edge are respectively connected with the first cutting edge and the first connection edge. The shortest distance between two ends of the first outer edge is defined as the primary cutting face width. The primary cutting face width is larger than the web thickness.

In one embodiment, the first secondary cutting face has a first blade back, a second prismatic edge, a second connection edge and a second outer edge. The second connection edge of the first secondary cutting face is connected with the first connection edge of the first primary cutting face. One end of the second outer edge is connected with one end of the first outer edge of the first primary cutting face to form an arc with the tip being the center. The arc functions as the first outer rim of the first cutting face. The arc has an included angle ranging from 60 to 200 degrees.

In one embodiment, the second primary cutting face has a triangle-like shape. The second primary cutting face includes a third prismatic edge, a third connection edge, and a third outer edge. The second secondary cutting face includes a second blade back, a fourth prismatic edge, a fourth connection edge, and a fourth outer edge. The third prismatic edge of the second primary cutting face is connected with the second prismatic edge of the first secondary cutting face. The third connection edge of the second primary cutting face is connected with the fourth connection edge of the second secondary cutting face. The fourth prismatic edge of the second secondary cutting face is connected with the first prismatic edge of the first primary cutting face. The fourth outer edge of the second secondary cutting face includes a first edge and a second edge connected with the first edge. Each of the first edge and the second edge is in form of an arc or a straight line. The second blade back of the second secondary cutting face is in form of a straight line and parallel with the fourth connection edge. In another embodiment, the second blade back of the second secondary cutting face is in form of an arc and smooth connected with the first cutting edge without any sharp angle.

In one embodiment, the first cutting face and the second cutting face are respectively arranged on two sides of the web. The first primary cutting face is corresponding to the second primary cutting face. The first secondary cutting face is corresponding to the second secondary cutting face. The second primary cutting face includes a third prismatic edge, a second cutting edge, a third connection edge and a third outer edge. The third connection edge is connected with the second secondary cutting face. One end of the third prismatic edge and one end of the third connection edge intersect at the tip. One end of the second cutting edge is connected with one end of the third prismatic edge, which is far away from the tip. The other end of the second cutting edge is extended to a direction far away from the third connection edge to make the second cutting edge not parallel with the third connection edge. Two ends of the third outer edge are respectively connected with the second cutting edge and the third connection edge. The shortest distance between two ends of the third outer edge is defined as the primary cutting face width.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1 is a diagram schematically showing a conventional cutting face structure of a drill structure;

FIG. 2 is a diagram schematically showing a drill structure according to one embodiment of the present invention;

FIG. 3 is a diagram schematically showing a cutting face structure according to a first embodiment of the present invention;

FIG. 4 is a diagram schematically showing a cutting face structure according to a second embodiment of the present invention; and

FIG. 5 is a diagram schematically showing a cutting face structure according to a third embodiment of the present invention.

### DESCRIPTION OF THE PREFERRED EMBODIMENTS

The present invention is described in detail with embodiments below. However, these embodiments are only to exemplify the present invention but not intended to limit the scope of the present invention.

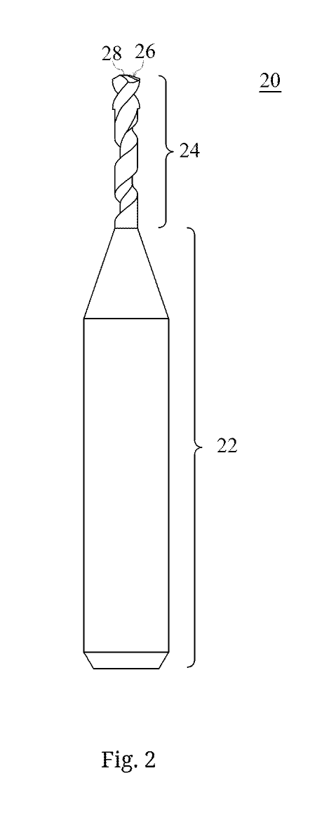

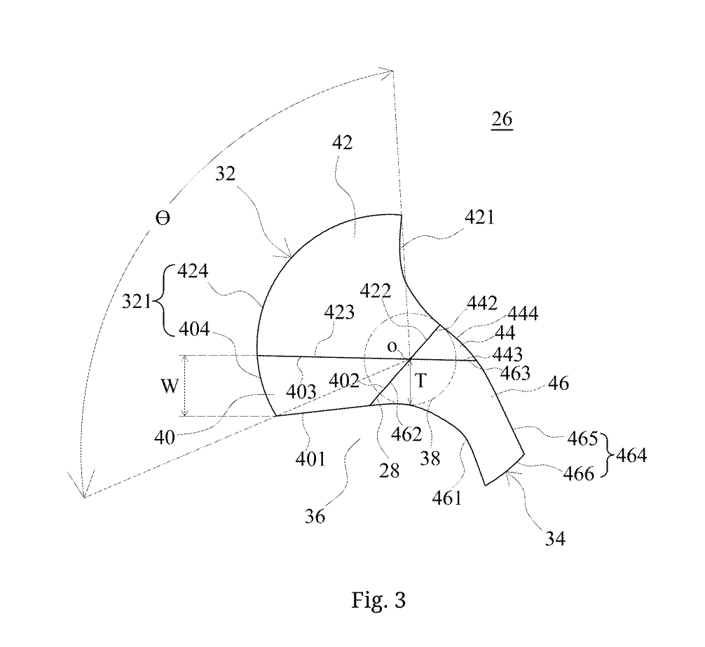

FIG. 2 is a diagram schematically showing a drill structure according to one embodiment of the present invention. As shown in FIG. 2, the drill structure 20 comprises a shank part 22 and a flute part 24 disposed at one end of the shank part 22. The front region of the flute part 24 has a cutting face structure 26. The cutting face structure 26 has a web 28. FIG. 3 is a diagram schematically showing a cutting face structure according to a first embodiment of the present invention. As shown in FIG. 3, the web 28 has a tip O functioning as the static web point of the drill structure 20. Two sides of the web 28 are respectively tilted toward the shank part 22 to form a first cutting face 32 and a second cutting face 34. In the first embodiment, the structure of the first cutting face 32 is different from the structure of the second cutting face 34. A first outer rim 321 of the first cutting face 32 is spirally extended toward the shank part 22 around the outer surface of the flute part 24 to form a first helical side edge (not shown in the drawing) and a first helical groove 36. Thus, the flute part 24 has a bit core 38 in the center thereof. The radius of the cross section of the bit core 38 is defined as the web thickness T.

The first cutting face 32 includes a first primary cutting face 40 and a first secondary cutting face 42. The second cutting face 34 includes a second primary cutting face 44 and a second secondary cutting face 46. The apexes of the first primary cutting face 40, the first secondary cutting face 42, the second primary cutting face 44 and the second secondary cutting face 46 intersect at the tip O of the web 28. The first primary cutting face 40 has a first cutting edge 401, a first prismatic edge 402, a first connection edge 403 and a first outer edge 404. One end of the first prismatic edge 402 and one end of the first connection edge 403 intersect at the tip O. The second primary cutting face 42 has a first blade back 421, a second prismatic edge 422, a second connection edge 423 and a second outer edge 424. One end of the second prismatic edge 422 and one end of the second connection edge 423 intersect at the tip O. The first connection edge 403 of the first primary cutting face 40 is connected with the second connection edge 423 of the first secondary cutting face 42. One end of the first cutting edge 401 of the first primary cutting face 40 is connected with one end of the first prismatic edge 402, which is far away from the tip O. The other end of the first cutting edge 401 is extended toward a direction far away from the first connection edge 403, whereby the first cutting edge 401 is not parallel with the first connection edge 403. Two ends of the first outer edge 404 are respectively connected with the first cutting edge 401 and the first connection edge 403. The shortest distance between two ends of the first outer edge 404 is defined as the width W of the first primary cutting face 40. The width W of the first primary cutting face 40 is larger than the web thickness T. Therefore, the first primary cutting face 40 is gradually widened from the tip O to the first outer edge 404.

Refer to FIG. 3 again. One end of the second outer edge 424 of the first secondary cutting face 42 is connected with one end of the first outer edge 404 of the first primary cutting face 40. The first outer edge 404 and the second outer edge 424 jointly form an arc with the tip O being the center. The arc is equal to the first outer rim 321 of the first cutting face 32. In the first embodiment, the included angle θ of the arc is 120 degrees. However, the present invention is not limited by the first embodiment. In other embodiments, the included angle θ of the arc ranges from 60 to 200 degrees.

In the first embodiment, the second primary cutting face 44 has a triangle-like shape, including a third prismatic edge 442, a third connection edge 443, and a third outer edge 444. In the first embodiment, the second secondary cutting face 46 includes a second blade back 461, a fourth prismatic edge 462, a fourth connection edge 463, and a fourth outer edge 464. The third prismatic edge 442 of the second primary cutting face 44 is connected with the second prismatic edge 422 of the first secondary cutting face 42. The third connection edge 443 of the second primary cutting face 44 is connected with the fourth connection edge 463 of the second secondary cutting face 46. The fourth prismatic edge 462 of the second secondary cutting face is connected with the first prismatic edge 402 of the first primary cutting face 40. In the first embodiment shown in FIG. 3, the second blade back 461 is arc-shaped and smooth connected with the first cutting edge 401 without any sharp angle. The fourth outer edge 464 includes a first edge 465 and a second edge 466 connected with the first edge 465. Each of the first edge 465 and the second edge 466 may be in form of an arc or a straight line. One end of the second edge 466 is connected with one end of the second blade back 461.

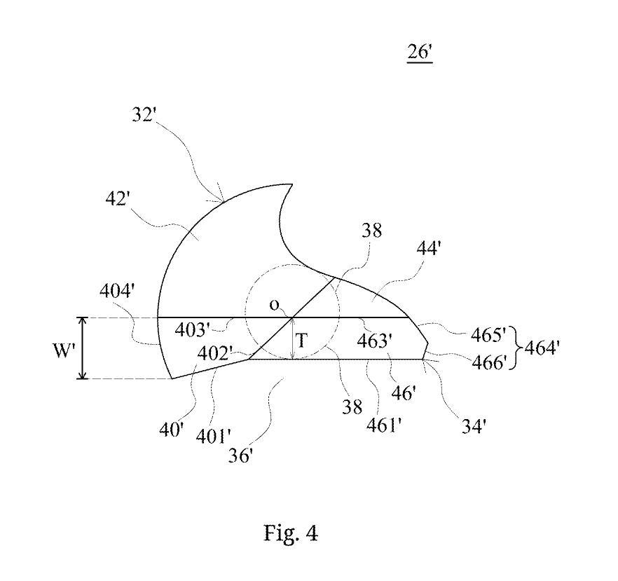

FIG. 4 is a diagram schematically showing a cutting face structure according to a second embodiment of the present invention. The second embodiment is essentially similar to the first embodiment. In the second embodiment, the first cutting face 32′ of the cutting face structure 26′ includes a first primary cutting face 40′ and a first secondary cutting face 42′. The second cutting face 34′ includes a second primary cutting face 44′ and a second secondary cutting face 46′; the apexes of the first primary cutting face 40′, the first secondary cutting face 42′, the second primary cutting face 44′ and the second secondary cutting face 46′ intersect at a tip O. One end of the first cutting edge 401′ of the first primary cutting face 40′ is connected with one end of the first prismatic edge 402′ of the first primary cutting face 40′, which is far away from the tip O. The other end of the first cutting edge 401′ is extended to a direction far away from the first connection edge 403′, whereby the first cutting edge 401′ is not parallel with the first connection edge 403′. Two ends of the first outer edge 404′ are respectively connected with the first cutting edge 401′ and the first connection edge 403′. The shortest distance between two end points of the first outer edge 404′ is defined as the width W′ of the first primary cutting face 40′. The width W′ of the first primary cutting face 40′ is larger than the web thickness T. Therefore, the first primary cutting face 40′ is gradually widened from the tip O to the first outer edge 404′.

The second embodiment is different from the first embodiment in that the second blade back 461′ of the second secondary cutting face 46′ is in form of a straight line and parallel to the fourth connection edge 463′ in the second embodiment. The fourth outer edge 464′ includes a first edge 465′ and a second edge 466′. The fourth outer edge 464′ is connected with one end of the second blade back 461′ and one end of the fourth connection edge 463′, which is far away from the tip O.

In the abovementioned first embodiment and second embodiment, the first cutting face 32 (32′) is asymmetric with the second cutting face 34 (34′). Each of the first embodiment and second embodiment only has a single first cutting edge 401(401′) and a single first helical groove 36 (36′). In the first embodiment and second embodiment, the first cutting edge 401 (401′) is extended obliquely to be not parallel with the first connection edge 403 (403′), whereby the first cutting edge 401 (401′) has longer cutting length and higher cutting ability. In the present invention, the width W of the first primary cutting face 40 (40′) is larger than the web thickness T. Thus, the first primary cutting face 40 (40′) is gradually widened from the tip O to the first outer edge 404 (404′). Therefore, the first primary cutting face 40 (40′) has larger area and longer service life.

In the present invention, the design that the width W of the first primary cutting face is larger than the web thickness is also applied to a dual-cutting edge and dual-groove drill structure, in addition to the single-cutting edge drill structure of the first and second embodiments.

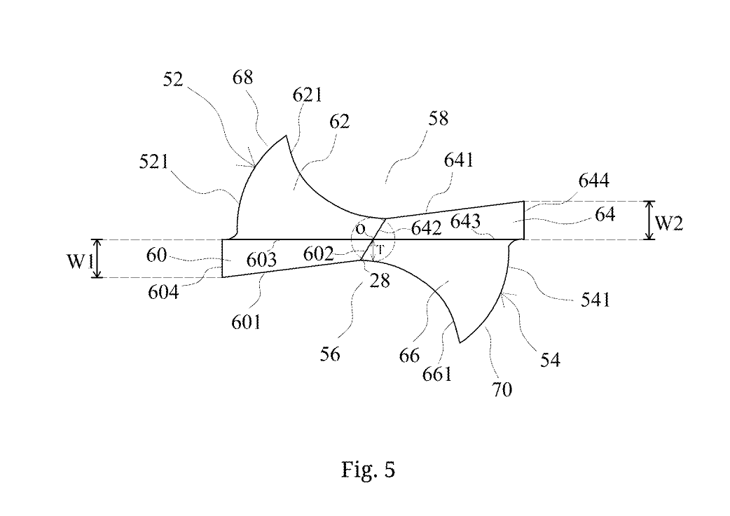

FIG. 5 is a diagram schematically showing a cutting face structure according to a third embodiment of the present invention. As shown in FIG. 5, a first cutting face 52 and a second cutting face 54 are oppositely disposed on two sides of the web 28. A first primary cutting face 60 is corresponding to a second primary cutting face 64. A first secondary cutting face 62 is corresponding to a second secondary cutting face 66. The apexes of the first primary cutting face 60, the first secondary cutting face 62, the second primary cutting face 64 and the second secondary cutting face 66 intersect at the tip O. A first outer rim 521 of the first cutting face 52 and a second outer rim 541 of the second cutting face 54 are spirally extended around the surface of the flute part 24 (shown in FIG. 2) toward the shank part 22 (shown in FIG. 2) to form a first helical side edge (not shown in FIG. 5), a first helical groove 56, a second helical side edge (not shown in FIG. 5), and a second helical groove 58. Thus, the flute part 24 has a bit core 38 in the center thereof. The radius of the cross section of the bit core 38 is defined as the web thickness T.

Refer to FIG. 5 again. The first primary cutting face 60 has a first cutting edge 601, a first prismatic edge 602, a first connection edge 603 and a first outer edge 604. One end of the first prismatic edge 602 and one end of the first connection edge 603 intersect at the tip O. The second primary cutting face 64 has a second cutting edge 641, a third prismatic edge 642, a third connection edge 643 and a third outer edge 644. The third connection edge 643 is connected with the second secondary cutting face 66. One end of the third prismatic edge 642 and one end of the third connection edge 643 intersect at the tip O. The first cutting edge 601 of the first primary cutting face 60 and the second cutting edge 641 of the second primary face 64 are respectively connected with two ends of the web 28. The other end of the first cutting edge 601 is extended to a direction far away from the first connection edge 603, whereby the first cutting edge 601 is not parallel with the first connection edge 603. The other end of the second cutting edge 641 is extended to a direction far away from the third connection edge 643, whereby the second cutting edge 641 is not parallel with the third connection edge 643. Thus, the widths W1 and W2 of the primary cutting faces, which are respectively defined by the shortest distance between two ends of the first outer edge 604 and the shortest distance between two ends of the third outer edge 644, are larger than the web thickness T. In other words, the first primary cutting face 60/the second primary cutting face 64 is gradually widened from the tip O to the first outer edge 604/the second outer edge 644.

A first edge groove 68 is formed from a portion of the first outer rim 521 and along the first helical side edge. The first edge groove 68 neighbors the first blade back 621. A second edge groove 70 is formed from a portion of the second outer rim 541 and along the second helical side edge. The second edge groove 70 neighbors the second blade back 661.

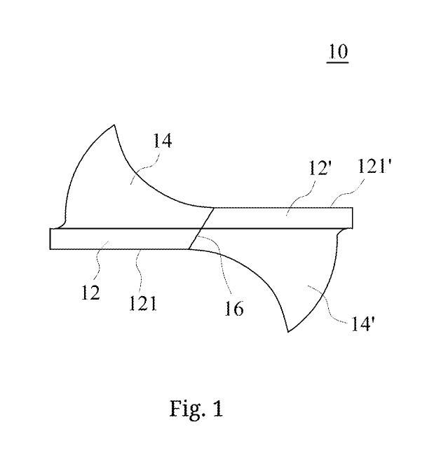

In the cutting face structure of the third embodiment, the first cutting edge 601/the second cutting edge 641 is not parallel with the first connection edge 603/the third connection edge 643 but oblique to the first connection edge 603/the third connection edge 643. Compared with the conventional cutting edge 121 (shown in FIG. 1), the first cutting edge 601/the second cutting edge 641 have longer cutting length and high cutting force. Further, the cutting face width W1/W2 of the first primary cutting face 60/the second primary cutting face 64 is larger than the web thickness T. Thus, the first primary cutting face 60/the second primary cutting face 64 is gradually widened from the tip O to the first connection edge 603/the third connection edge 643. Therefore, the first primary cutting face 60/the second primary cutting face 64 has larger area and longer service life.

In conclusion, no matter whether the drill structure of the present invention is a single-cutting edge or a dual-cutting edge one, the cutting face width of the primary cutting face is larger than the web thickness. Therefore, the primary cutting face has longer cutting length and higher cutting force. Further, the primary cutting face has larger area and longer service life.

What is claimed is:

1. A drill structure comprising
a shank part; and
a flute part arranged in one end of the shank part, wherein a cutting face structure is formed in a front end of the flute part; the cutting face structure includes a web; the web has a tip; two sides of the web are spirally extended backward to form a first cutting face and a second cutting face; at least one first outer rim of the first cutting face is spirally extended backward around an outer surface of the flute part to form at least one first helical side edge and at least one first helical groove; the flute part has a bit core; a radius of a cross section of the bit core is defined as a web thickness; the first cutting face includes a first primary cutting face and a first secondary cutting face; the second cutting face includes a second primary cutting face and a second secondary cutting face; apexes of the first primary cutting face, the first secondary cutting face, the second primary cutting face and the second secondary cutting face intersect at the tip; the first primary cutting face has a first cutting edge, a first prismatic edge, a first connection edge and a first outer edge; the first prismatic edge is connected with the second secondary cutting face; the first connection edge is connected with the first secondary cutting face; one end of the first prismatic edge and one end of the first connection edge intersect at the tip; one end of the first cutting edge is connected with one end of the first prismatic edge, which is far away from the tip; the other end of the first cutting edge is extended to a direction far away from the first connection edge to make the first cutting edge not parallel with the first connection edge; two ends of the first outer edge are respectively connected with the first cutting edge and the first connection edge; the shortest distance between two ends of the first outer edge is defined as a primary cutting face width; the primary cutting face width is larger than the web thickness.

2. The drill structure according to claim 1, wherein the first secondary cutting face has a first blade back, a second prismatic edge, a second connection edge and a second outer edge; the second connection edge of the first secondary cutting face is connected with the first connection edge of the first primary cutting face; one end of the second outer edge is connected with one end of the first outer edge of the first primary cutting face to form an arc with the tip being a center; the arc functions as the first outer rim of the first cutting face; the arc has an included angle ranging from 60 to 200 degrees.

3. The drill structure according to claim 2, wherein the second primary cutting face has a triangle-like shape; the second primary cutting face includes a third prismatic edge, a third connection edge, and a third outer edge; the second secondary cutting face includes a second blade back, a fourth prismatic edge, a fourth connection edge, and a fourth outer edge; the third prismatic edge of the second primary cutting face is connected with the second prismatic edge of the first secondary cutting face; the third connection edge of the second primary cutting face is connected with the fourth connection edge of the second secondary cutting face; the fourth prismatic edge of the second secondary cutting face is connected with the first prismatic edge of the first primary cutting face.

4. The drill structure according to claim 3, wherein the fourth outer edge of the second secondary cutting face includes a first edge and a second edge connected with the first edge; each of the first edge and the second edge is in form of an arc or a straight line.

5. The drill structure according to claim 3, wherein the second blade back of the second secondary cutting face is in form of a straight line and parallel with the fourth connection edge.

6. The drill structure according to claim 3, wherein the second blade back of the second secondary cutting face is in form of an arc and smooth connected with the first cutting edge without any sharp angle.

7. The drill structure according to claim 2, wherein the first cutting face and the second cutting face are respectively arranged on two sides of the web; the first primary cutting face is corresponding to the second primary cutting face; the first secondary cutting face is corresponding to the second secondary cutting face; the second primary cutting face includes a third prismatic edge, a second cutting edge, a third connection edge and a third outer edge; the third connection edge is connected with the second secondary cutting face; one end of the third prismatic edge and one end of the third connection edge intersect at the tip; one end of the second cutting edge is connected with one end of the third prismatic edge, which is far away from the tip; the other end of the second cutting edge is extended to a direction far away from the third connection edge to make the second cutting edge not parallel with the third connection edge; two ends of the third outer edge are respectively connected with the second cutting edge and the third connection edge; the shortest distance between two ends of the third outer edge is defined as a primary cutting face width.

8. The drill structure according to claim 7, wherein a second outer rim of the second cutting face is spirally extended backward around an outer surface of the flute part to form a second helical side edge and a second helical groove; the flute part has a bit core in a center thereof.

9. The drill structure according to claim 8, wherein a first edge groove is formed from a portion of the first outer rim and along the first helical side edge; the first edge groove neighbors the first blade back of the first secondary cutting face; a second edge groove is formed from a portion of the second outer rim and along the second helical side edge; the second edge groove neighbors the second blade back of the second secondary cutting face.

10. The drill structure according to claim 1, wherein the first primary cutting face is gradually widened from the tip to the first outer edge.
